(19) United States
(12) Patent Application Publication
(10) Pub. No.: US 2026/0289044 A1
(43) Pub. Date: Sep. 24, 2026

(54) DATA-DRIVEN MODEL FOR BATTERY STATES PREDICTION

(71) Applicant: Hong Kong Applied Science and Technology Research Institute Co., Ltd, Shatin (HK)

(72) Inventors: Lunte LI, Shenzhen (CN); Jing XIANG, Shatin (HK); Laiyong XIE, Shenzhen (CN)

(21) Appl. No.: 19/083,798

(22) Filed: Mar. 19, 2025

(51) Int. Cl. G06F 30/27

(52) U.S. Cl. CPC G06F 30/27

(57) ABSTRACT

A method for predicting a state parameter for a battery, comprising steps of: (i) obtaining an input dataset comprising time series voltage and current data of the battery during a portion of a charge cycle or a discharge cycle; (ii) reducing dimensionality of the input dataset by a first neural network to form a reduced dataset with a predetermined dimension; (iii) extracting temporal dynamic features from the reduced dataset by a second neural network, wherein the second neural network processes the reduced dataset by a neural ordinary differential equation; and (iv) predicting the state parameter based on the extracted temporal dynamic features.

### TECHNICAL FIELD

The present invention relates to a method for predicting a state parameter for a battery. More particularly, the present invention relates to a method for predicting a state parameter for a battery using machine learning methods.

### BACKGROUND

Accurate prediction of the states of a battery is critical to ensure efficient and safe operation thereof. There are several approaches to battery state prediction on the market, the simplest of which is to make direct measurements of a battery's capacity or resistance over time to estimate the battery state. Such a method has low computational cost, but is also time consuming to make all the measurements manually.

Alternative methods include deduction by experience and simulation based on battery models (RC model, P2D model, etc.), but these methods have low accuracy since they lack specificity to a particular battery type. Further, it would be difficult to develop battery models that accurately mimic the complex structure of batteries.

Another method is to predict using a data-driven model based on machine learning. This method is widely adopted within the field because the modelling is simple and does not require much manual work. However, most of the existing data-driven models do not provide high accuracy. In fact, the majority of these models have an error of more than 3% and therefore cannot be used in practical applications. High-performing data-driven models may provide more accurate prediction results. However, they tend to be computationally intensive and have high computational requirements, resulting in a low operational efficiency. In addition, these high-performance data-driven models always require extended training sets and a computation time that is typically more than 30 times higher than other models.

The invention seeks to mitigate or to at least alleviate such a problem or shortcoming by providing a new or otherwise improved method accurately predicting battery states.

### SUMMARY OF THE INVENTION

According to a first aspect of the present invention, there is provided a method for predicting a state parameter for a battery, comprising steps of: (i) obtaining an input dataset comprising time series voltage and current data of the battery during a portion of a charge cycle or a discharge cycle; (ii) reducing dimensionality of the input dataset by a first neural network to form a reduced dataset with a predetermined dimension; (iii) extracting temporal dynamic features from the reduced dataset by a second neural network, wherein the second neural network processes the reduced dataset by a neural ordinary differential equation; and (iv) predicting the state parameter based on the extracted temporal dynamic features.

In an embodiment, the method further comprises a step of subjecting the extracted temporal dynamic features to a pull and drop by a third neural network, prior to predicting the state parameter in step (iv).

In an embodiment, the method further comprises a step of applying a sliding window to the input dataset, wherein the sliding window divides the input dataset into a plurality of segments, such that a state parameter is predicted for each of the plurality of segments.

In an embodiment, the sliding window has a width of an hour.

In an embodiment, the method further comprises a step of integrating an embedding layer comprising temperature data of the battery to the extracted temporal dynamic features, prior to predicting the state parameter in step (iv).

In an embodiment, the temperature data of each of the plurality of segments is an averaged temperature within a respective segment.

In an embodiment, the state parameter is selected from any one of a state of charge, a state of health, a capacity, a state of power, a remaining useful life of the battery, or a combination thereof.

In an embodiment, the method further comprises a step of feeding an averaged state parameter to the third neural network for training thereof, wherein the averaged state parameter is a weighted average of a plurality of state parameters predicted from the plurality of segments within the same charge cycle or the same discharge cycle.

In an embodiment, the state parameter comprises two or more state parameters comprising a state of charge, a state of health, a capacity, a state of power, a remaining useful life of the battery, wherein the two or more state parameters are simultaneously predicted.

In an embodiment, the first neural network is selected from any one of an autoencoder, a recurrent neural network, a convolutional neural network, a generative adversarial network, an attention-based network, a long short-term memory, a gated recurrent unit, or a combination thereof.

In an embodiment, the second neural network is an ordinary differential equation based neural network.

In an embodiment, the third neural network is selected from any one of an autoencoder, a recurrent neural network, a convolutional neural network, a generative adversarial network, an attention-based network, a long short-term memory, a gated recurrent unit, or a combination thereof.

In an embodiment, the method comprises a step of confirming whether the reduced dataset has reached the predetermined dimension, prior to extracting the temporal dynamic features in step (iii).

In an embodiment, the predetermined dimension of the reduced dataset is between 1/64 and ½ of a dimension of the input dataset.

According to a second aspect of the present invention, there is provided a data-driven model for battery state prediction, comprising a differential equation-based neural network for feature extraction, where dimensionality reduction techniques using various neural network architectures are applied prior to differential equation processing.

In an embodiment, the dimensionality reduction technique is implemented through a series of multi-layer neural network architectures, including but not limited to autoencoders, recurrent neural networks, convolutional neural networks, generative adversarial networks, and attention-based networks, enabling dimensionality reduction such that the reduced data represents between 1/64 and ½ of the original data.

In an embodiment, a sliding window technique is applied to the time-series charging data.

In an embodiment, an embedding layer integrates temperature data.

In an embodiment, predictions from segments of the same cycle are averaged during training to aggregate SOH and capacity outputs.

An embodiment of the present invention comprises a hybrid convolution neural network and an ordinary differential equation based neural network module. It provides high-accuracy multi-state predictions (state of charge, state of health, and capacity) with lower computational costs and real-time deployment.

### BRIEF DESCRIPTION OF THE DRAWINGS

The invention will now be more particularly described, by way of example only, with reference to the accompanying drawings, in which:

FIG. 1 is a flow chart showing an embodiment of a method for predicting battery state according to the present invention;

FIG. 2 is a flow chart showing another embodiment of a method for predicting battery state according to the present invention;

FIG. 3 is a schematic diagram showing the principles of operation of a neural network used in an embodiment of the present invention to reduce the dimensionality of input data;

FIG. 4a is a graph showing principles of operation of a differential equation-based neural network (NODE) used in an embodiment of the present invention to capture temporal dynamic features of data;

FIG. 4b is a graph showing a model feature evolution across layers of a convolutional neural network;

FIG. 4c is a graph showing a model feature evolution over time of a differential equation based neural network;

FIG. 5 is a schematic diagram showing an algorithm architecture of the method of FIG. 2;

FIG. 6 is a computational graph of the method of FIG. 2;

FIG. 7 are graphs demonstrating application of a sliding window to the input data, in accordance to an embodiment of the present invention;

FIG. 8 is a graph showing the measured, fitted and padded voltage and current using the sliding window of FIG. 7;

FIG. 9 is a flow chart showing a process for training a model used in an embodiment of the present invention;

FIG. 10 includes a pie chart and a table showing the datasets utilised in the training process of FIG. 9;

FIG. 11 is a flowchart showing an aggregation of prediction outputs during the training process of FIG. 9, accompanied by a sliding window technique;

FIG. 12 are graphs showing predicted state of charge (SOC), state of health (SOH) and capacity outputs from the segments of a same charging or discharging cycle;

FIG. 13a is a graph demonstrating the accuracy of predicting the state of charge of a battery using an embodiment of a method according to the present invention;

FIG. 13b is a graph demonstrating the accuracy of predicting the capacity of a battery using an embodiment of a method according to the present invention;

FIG. 13c is a graph demonstrating the accuracy of predicting the state of health of a battery using an embodiment of a method according to the present invention;

FIG. 14a is a graph showing a comparison in runtime between a pure CNN, a pure NODE, and an embodiment of a model used in the present invention;

FIG. 14b is a graph showing a comparison in root mean square deviation and mean absolute error between a pure CNN, a pure NODE and an embodiment of a model used in the present invention;

FIG. 14c is a graph showing a comparison in R-square value between a pure CNN, a pure NODE and an embodiment of a model used in the present invention; and

FIG. 15 is a table showing a comparison of computational complexity with dimensionality retention ratio of data.

### DETAILED DESCRIPTION OF THE EMBODIMENTS

To alleviate at least some of the deficiencies of the prior art, an embodiment of a data-driven prediction model according to the present invention uses machine learning methods to provide accurate prediction results. It comprises a neural network adapted for dimensionality reduction of the input data, a differential equation-based neural network, and in an embodiment also a sliding window technique. With the advantages of lower computational requirements and effectiveness in capturing deep time series relationships, highly efficient and highly accurate battery state prediction could be achieved. In addition, the sliding window technique effectively handles segmented time-series data and smooths fluctuations, making it more suitable for real-time applications. The differential equation-based neural network models continuous feature evolution over time through an ODE solver, achieving smooth transitions and effectively capturing temporal dynamics in time-series data. The proposed model demonstrates very high prediction accuracy on the test set.

It is expected that the invention enhances product reliability and battery lifespan, offering competitive advantages to manufacturers, battery management system (BMS) developers, and original equipment manufacturers (OEMs).

### 1. PREDICTION MODEL AND METHOD

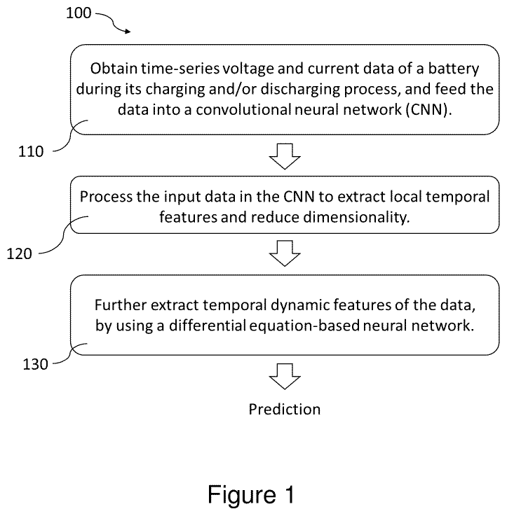

An embodiment of a method 100 for predicting battery state according to the present invention is demonstrated in FIG. 1. The method 100 comprising a first step 110 of obtaining voltage and current data of a battery during its charging and/or discharging process, and feeding the obtained data into a convolutional neural network (CNN). In particular, a plurality of voltage and current data of a battery are measured at predetermined time intervals to provide a dataset comprising time-series voltage and current values of the battery. In an embodiment, the voltage and current data are obtained during a portion, but not the entirety, of the charging or discharging process of the battery.

After obtaining a data set comprising time series voltage and current data of a battery, the method 100 undergoes a second step 120 in which the obtained data set is input to a neural network for extraction of local temporal features and dimensionality reduction. In an embodiment, the neural network includes, but is not limited to, autoencoders, recurrent neural networks, convolutional neural networks, generative adversarial networks, and attention-based networks that enable dimensionality reduction. In particular, the dimensionality reduction step 120 is completed prior to step 130 in which temporal dynamic features of the dataset are further extracted using a differential equation based neural network. This ensures that the data set is in a reduced and optimal dimension prior to differential equation processing, allowing efficient and accurate extraction of the temporal dynamic features for accurate battery state prediction.

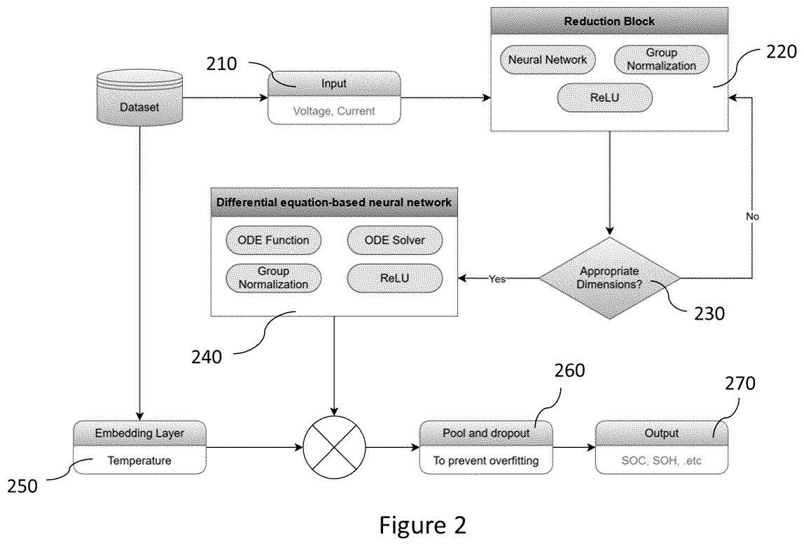

FIG. 2 shows a process flow diagram of a data driven model 200 according to the present invention. Initially, time series data of the voltage and current 210 of the battery measured during its charging and/or discharging process is input to a reduction block 220 operated by a neural network. The reduction block 220 extracts local temporal features from the input time series data 210 using a convolutional neural network in conjunction with group normalization and a rectified linear unit (ReLU), and reduces its dimension to a predetermined optimal level. In an embodiment, the optimal dimension of the reduced data set is between 1/64 and ½ of the original time series data 210. In an embodiment, the data driven model 200 provides a logic check 230 to check whether the dimension of the reduced data set has reached the optimal level. If so, it proceeds to the next step. However, if the reduced dataset has not yet reached the optimal dimension, the dataset continues to be dimensionally reduced in the reduction block 220 until the optimal dimension is reached. The optimal level of dimension is determined based on the performance of different dimensionality reduction scales on the training set.

After confirming that the reduced data set has reached an optimal dimension, the reduced data set is then passed to a differential equation based neural network (NODE) 240 which further captures the complex temporal dependencies and temporal dynamic features of the reduced data using a convolutional neural network, ordinary differential equations (ODE), an ODE solver, group normalisation techniques and a ReLU. The data extracted by the differential equation based neural network is then integrated with an embedding layer 250 comprising time series temperature data of the battery to enable the model 200 to adapt to different operating conditions and to provide further insight into the prediction results. The integrated data is then subjected to a pull and drop 260 to further reduce the dimensionality of the features and prevent overfitting. Finally, the extracted features are transformed into the final output targets via the dense procedures and multiple state parameters 270 including state of health, state of charge, and capacity of the battery are simultaneously output.

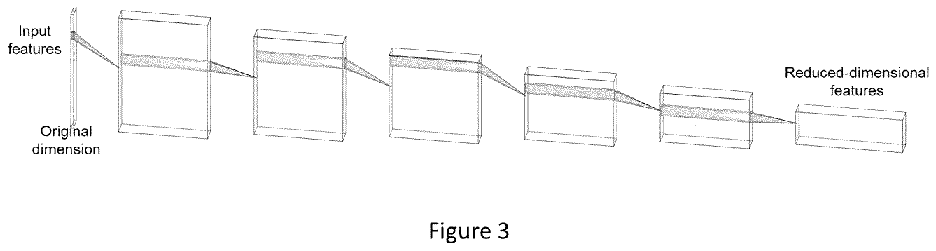

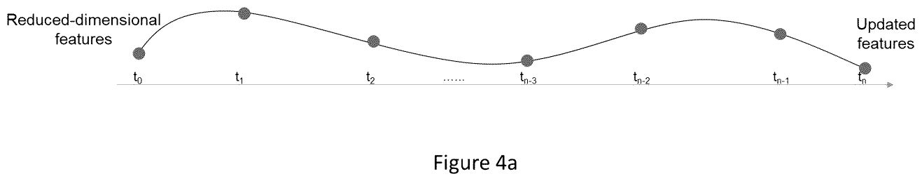

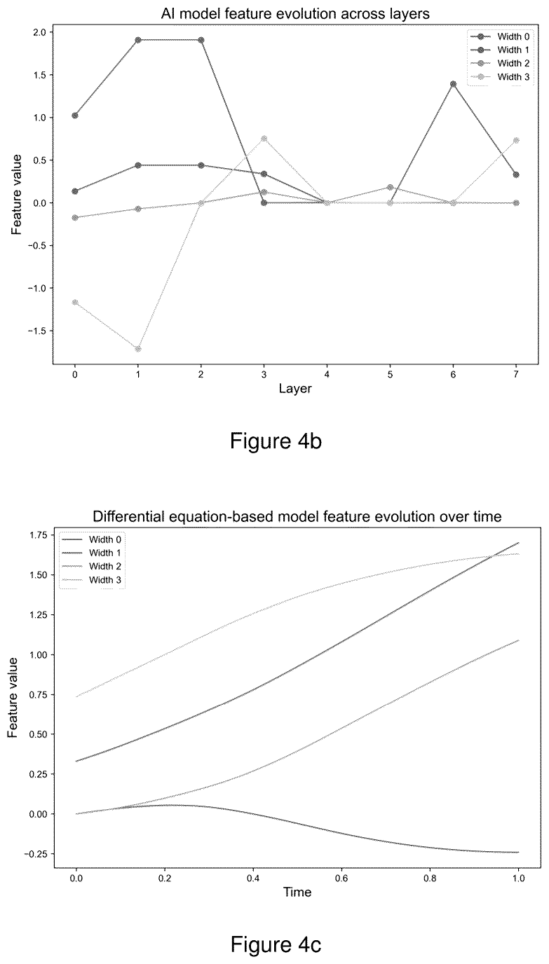

FIGS. 3 and 4a show the operating principles of a neural network and a differential equation based neural network (NODE) used in an embodiment of the present invention. In an embodiment, neural networks such as a convolutional neural network (CNN), a recurrent neural network (RNN), a long short-term memory (LSTM) and a gated recurrent unit (GRU) is used for dimensionality reduction, which retain 1/64 to ½ of the original data while extracting temporal features from the time series voltage and current data. This process requires little computation and is highly efficient. The differential equation based neural network (NODE) captures the temporal dynamics of the data by modelling the continuous evolution of the features over time, as shown by the curve in FIG. 4a, using an ordinary differential equation (ODE) solver. The ODE solver performs a numerical integration of the feature evolution over time and the resulting solution is used to update the input features. The differential equation based neural network is effective in capturing deep time series relationships, such as the time series voltage and current data of the present invention, and provides results with high accuracy. FIG. 4b shows the evolution of AI features across different layers of the network when using a conventional convolutional neural network, which can have large discrepancies in features between layers. Whereas, as shown in FIG. 4c, the feature evolution over time is continuous using a differential equation based neural network, achieving smooth transitions and effectively capturing the temporal dynamics in time series data.

### 2. ALGORITHM ARCHITECTURE

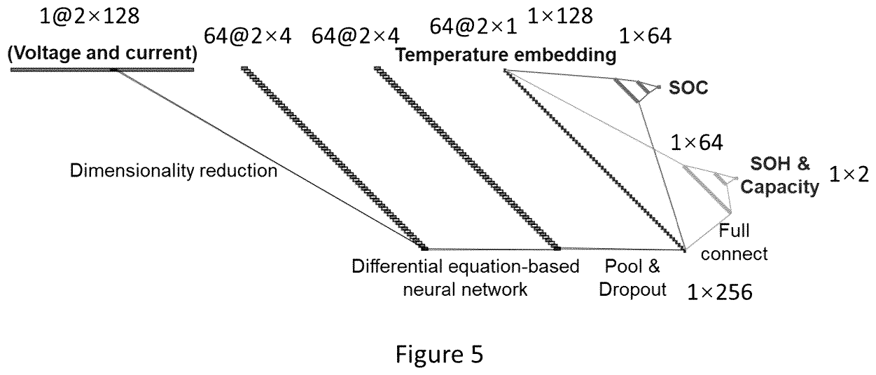

FIG. 5 illustrates the algorithm architecture of an embodiment of the data-driven model, which is implemented using Pytorch, according to the present invention. A convolutional block with 6 Conv2d layers has been established to reduce the input from 2×128 to 2×4 with 64 channels. A NODE block is added to retrieve deeper features while keeping the dimension identical. An average pooling layer is added to further reduce the feature to 2×1, which acts as the final feature corresponding to the segment. A fully connected (FC) layer with a hidden dimension of 64 is then connected to predict the SOC. All segment features are aggregated and averaged to form the cycle feature, which is used to predict the SOH or capacity. The temperature embedding is also added before the fully connected layer. Therefore, the final feature for SOH has a dimension of 64×2+128=256. An FC layer with a hidden dimension of 64 is also implemented for the final output.

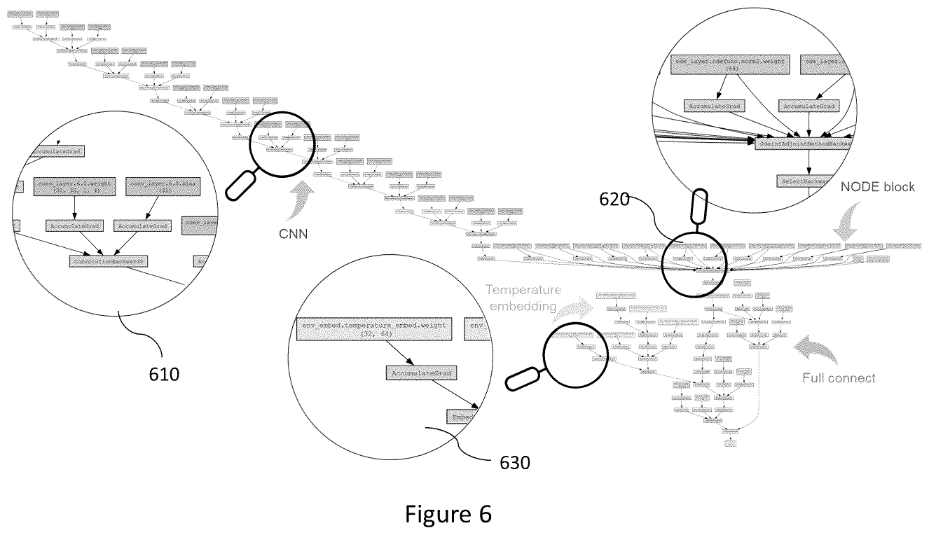

FIG. 6 shows a computational graph of the data-driven model of FIG. 5. In an embodiment, the data-driven model comprises 6 convolution blocks 610 for performing a series of convolution operations on the input data and extracting local spatial features, 2 NODE blocks 620 for processing features using the method of neural ordinary differential equations (NODE) and introducing temporal dynamics into the network, and 1 embedded block 630 to embed the temperature data into a high-dimensional space and combine it with the features from the other layers.

### 3. SLIDING WINDOW TECHNIQUE

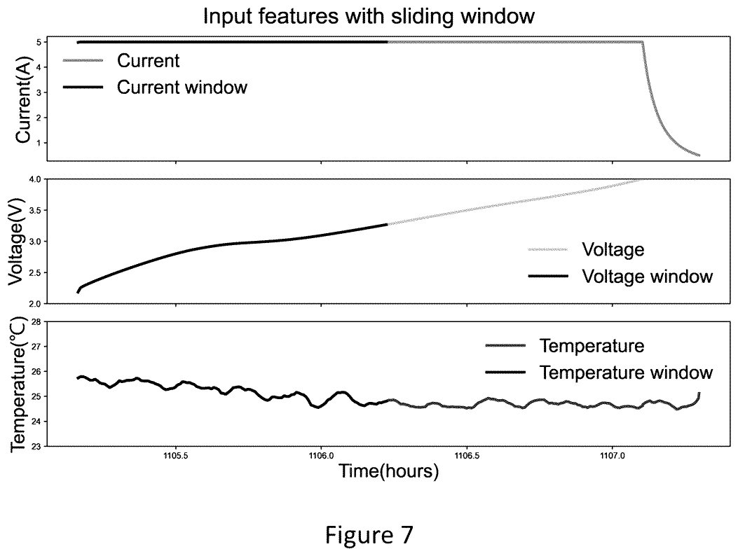

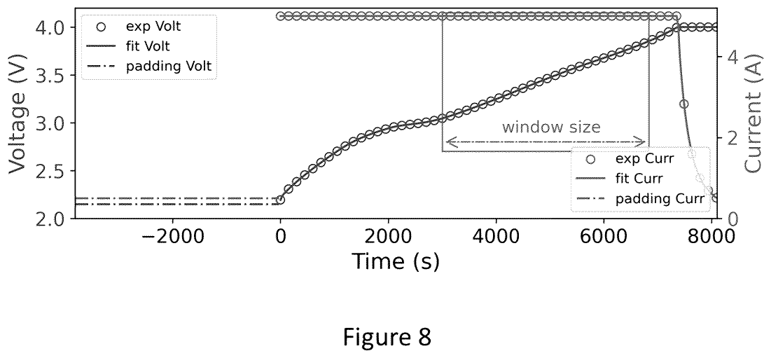

In an embodiment, a sliding window is applied to the time-series input data (voltage, current). FIG. 7 shows the sliding window technique applied to the input features including the current, voltage and temperature. For voltage and current, the series data of a sliding window is used directly, whereas for temperature, a single numerical value, or more specifically the average of the temperatures, is used for the same input within this sliding window. The sliding window technique effectively handles segmented time series data, smoothing fluctuations and making it more suitable for real time applications. In order to include the very early stage of the charging process and also to make the model suitable for partial charging curves, the charging curves are divided into continuous segments (as shown in FIG. 8). For each segment, the length of the input is controlled by the hyperparameter of window_size.

To prepare for the model input, the voltage and current are scaled into the range of [0,1] according to the equation of V_{scale}=(V−2.15)/(4−2.15) and I_{scale}=(I−0.5)/(5−0.5). Padding zeros are added before the initial charge state to make the first window_size−1 charging data points are available for model input.

### 4. TRAINING METHOD

### 4.1 Procedures

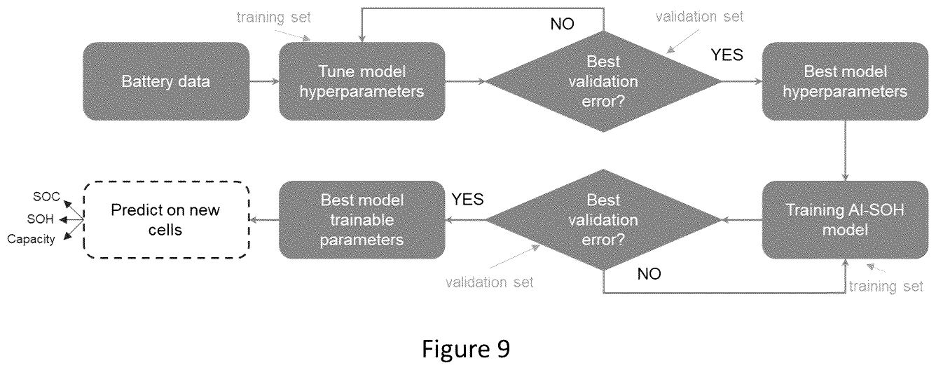

FIG. 9 shows a flow chart of the training process of the model according to an embodiment of the present invention. The model is trained simultaneously, utilizing only a single dataset. The sodium-ion battery cell NaCR32140-MP10 from HiNa Battery Technology was used, with a nominal capacity of 10 Ah, a nominal voltage of 3.05V and a charge-discharge voltage range of 2V to 4V at 25° C. Charge-discharge cycle tests were performed using the LAND system to generate a comprehensive data set. The test procedure, illustrated for 25° C., is as follows
1) A rest period of 5 minutes;
2) Constant current charging (CCC) at 5.0 A until the voltage reaches 4.0V;
3) Constant voltage charging (CVC) at 4.0V until the current decreases to 0.5 A;
4) A rest period of 5 minutes;
5) Constant current discharging (CCD) at 5.0 A until the voltage drops to 2.0V;
6) Steps 1)-5) are repeated for 3000 cycles.

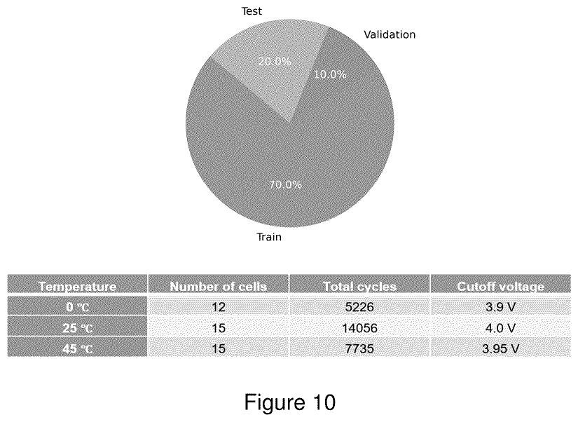

A total of 42 cells were tested under three temperature conditions: 12 cells at 0° C., 15 cells at 25° C. and 15 cells at 45° C. A total of 18,891 cycles were used for training, 2,695 cycles for validation and 5,431 cycles for testing. Details and statistics are shown in FIG. 10.

### 4.2 Equations and Parameters

The model is trained with a loss function, which is a weighted mean squared error (MSE), and balancing the prediction errors of SOC, SOH and capacity:

$$loss = gamma\_loss * SOC\_loss + ( 1 - gamma\_loss ) * ( SOH\_loss + Capacity\_loss ) ,$$

$$wherein the gamma\_loss = 0.2$$

$$ℒ = \frac{Y}{N} [ {\sum }_{n = 1}^{N} {( {SOC}_{n} - \tilde{{SOC}_{n}} )}^{2} ] + \frac{1 - γ}{2 M} [ {\sum }_{m = 1}^{M} {( {SOH}_{m} - \hat{{SOH}_{m}} )}^{2} + {\sum }_{m = 1}^{M} {( {Q}_{m} - {\hat{Q}}_{m} )}^{2} ]$$

The optimiser used is Adam, with a learning rate of Ir=3e-4 and a weight decay of 1e-6. The learning rate adjustment is set to be reduced every 30 epochs via StepLR. Other training parameters include the batch size, which is set to 16, and the epochs, which are set to 50.

Using a time window divides data from the same cycle into multiple segments, each with a different SOC. However, SOH and capacity should remain consistent.

4.3 Aggregation of Prediction Parameters, with the Sliding Window Technique

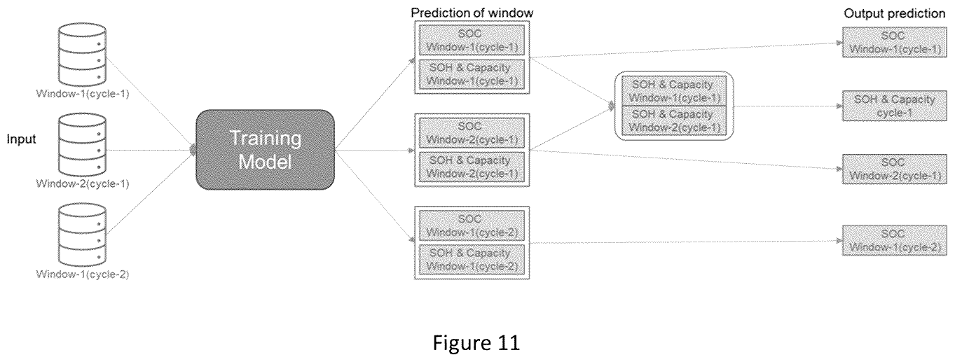

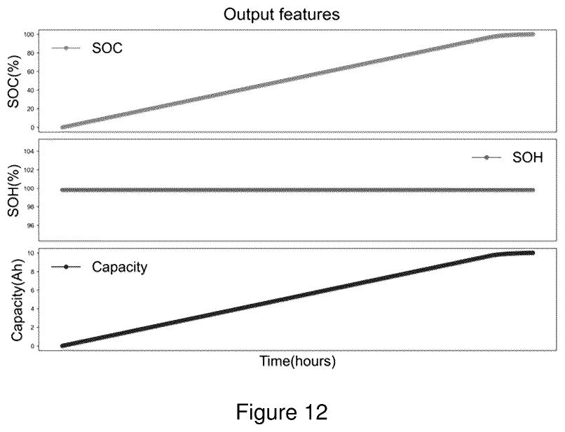

In an embodiment, a sliding window technique is applied to the input data and divides a charging and/or discharging cycle into a plurality of segments. Predictions from the plurality of segments within the same cycle are averaged during training to aggregate SOH and capacity outputs. To aggregate the predicted SOH and capacity outputs from the segments of the same cycle, each window was encoded by cycle and a weighted averaging method was applied during training. FIG. 11 shows a flowchart demonstrating the aggregation of prediction outputs during the training process, accompanied by a sliding window technique, while FIG. 12 are graphs showing predicted state of charge (SOC), state of health (SOH) and capacity outputs over time during a part of the charging and discharging cycle.

The averaging method used during training enables simultaneous prediction of multiple battery state parameters including SOC, SOH, Capacity, State of Power (SOP), Remaining Useful Life (RUL), which most existing data-driven models fail to do. Rather, the existing data-driven models usually focus on predicting either the state of health or state of charge of the battery. The averaging method accompanied by the sliding window techniques allows the simultaneous detection of different parameters because of the following reasons:
(i) Common Underlying State
   All segments within the same discharge and/or charge cycle of the battery share the same underlying battery state (e.g. degradation, temperature effects). By averaging segment level predictions, the method of the present invention aggregates information from multiple observations, thereby reducing noise and improving robustness.
(ii) Consistency Across Predictions
   The averaging method of the present invention ensures that predictions for long-term trend states (e.g., SOH, capacity, RUL) remain consistent within the same charge and/or discharge cycle, while still allowing for the immediate capture of short-term dynamics (e.g., SOC, SOP). This consistency is critical because these metrics are interrelated and depend on the same battery state.
(iii) Efficient Feature Utilization
   The averaging method of the present invention extracts high-dimensional features (segment_fea) from raw data (e.g., voltage/current curves) and pools them to generate cycle-level features (cycle_fea). These features capture both short-term dynamics (e.g., SOC, SOP) and long-term trends (e.g., SOH, capacity, RUL).

### 5. EXAMPLE

An example of the prediction model is implemented using Pytorch.

Firstly, the input data to the model. The input data consists of time series measurements of voltage and current from a battery charge/discharge cycle. Each input sample is a 2D tensor with dimensions [16, 1, 2, 128], where: 16 represents the batch size (single sample); 1 represents the one channels in Pytorch Conv2d; 2 represents the two “heights”: voltage and current; 128 represents the time steps (sliding window width).

The input data is first subjected to a dimensionality reduction procedure, where the input data is passed through a series of convolutional layers (conv_layer) to reduce its dimensionality. For example: reduced_data=conv_layer (input_data), where the retention ratio is set to 1/16 of the original input data. In this example, the feature map is reduced from 128 time steps to 8, while the number of channels is increased to 64. The reduced data is then processed by the ODE block, which models the continuous evolution of features over time: evolved_data=ode_block(reduced_data).

The ODEfunc class defines the continuous evolution of features over time, and the ODE solver uses the default solver from torchdiffeq: the dopri5 method (Dormand-Prince 5th-order adaptive step size algorithm). The ODE solver is integrated using odeint_adjoint over the time interval [0, 1], outputting the continuously evolved features.

The evolved features from the ODE block are then pooled and passed through fully connected layers to generate predictions. After dimensionality reduction (CNN), NODE, adaptive pooling, and dropout operations, the data is transformed into a feature vector of shape (b, 128), where b is the batch size. Concurrently, the normalized temperature values are encoded into a (b, 128) Tensor through a dedicated environmental model (EnvModel), which involves binning, embedding, and linear projection. These two Tensors are concatenated along the feature dimension to form a combined (b, 256) Tensor. This combined Tensor is fed into the SOH and Capacity prediction dense layer (fc2), while the original (b, 128) feature vector (without temperature) is separately passed to the SOC prediction dense layer (fc1).

The model returns two outputs, including segment_out, which refers to segment level predictions (e.g. State of Charge, SOC), and cycle_out, which refers to cycle level predictions (e.g. State of Health, SOH, and other battery states).

The example outputs are: segment_out=torch.tensor ([[0.65]]), cycle_out=torch.tensor ([[0.88, 8.5]]), where segment_out represents the predicted State of Charge (SOC) for a particular segment of the battery cycle (e.g, 65%), and cycle_out contains predictions for multiple battery states at the cycle level, such as State of Health (SOH) which is 88% (capacity retention relative to original capacity) and capacity which is 8.5 Ah (remaining usable capacity).

### 6. RESULTS

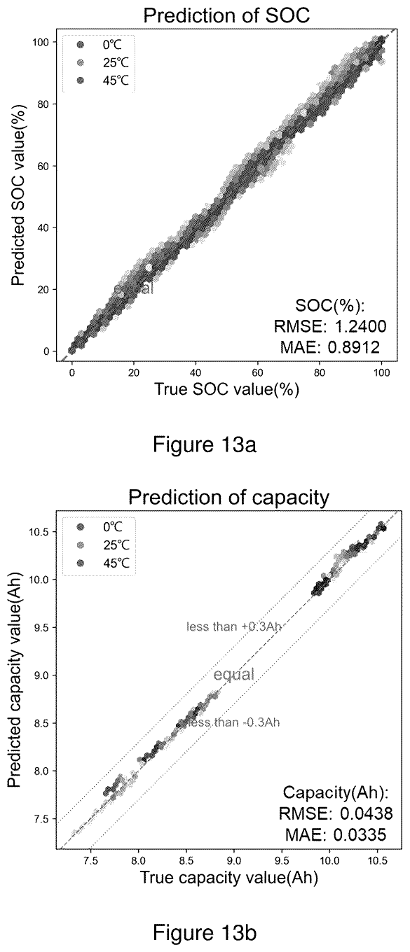

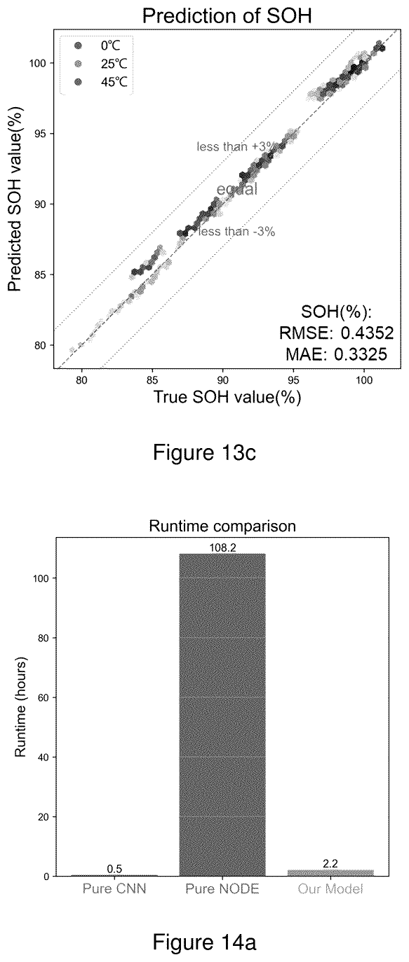

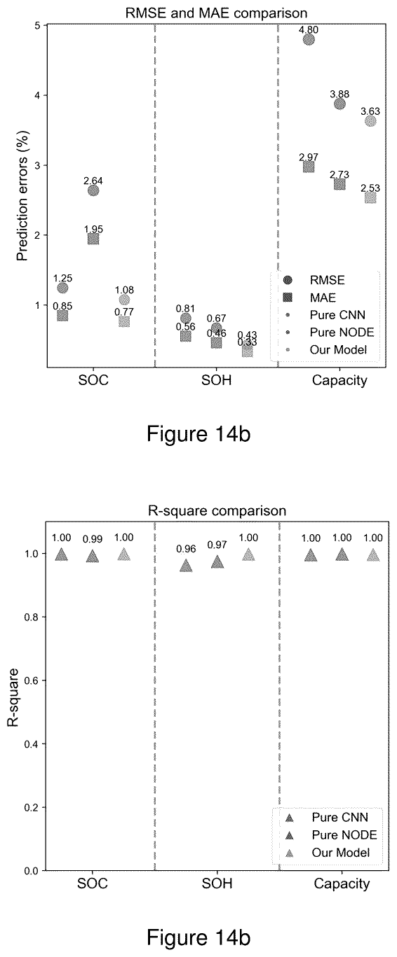

FIGS. 13a to 13c show the percentage accuracy in predicting the SOC, capacity and SOH of a battery which, as shown in the figures, achieves high accuracy for all predictions on the test set. FIGS. 14a to 14c show the comparison in (i) runtime, (ii) root mean square deviation, (iii) mean absolute error and (iv) R-squared value between a pure CNN, a pure NODE and an embodiment of a model used in the present invention. From these figures, it can be seen that although the pure CNN model is the most efficient of the three models and requires the shortest running time, its prediction results lack accuracy. At the other extreme, the pure NODE lacks efficiency when dealing with high dimensional data. The model of an embodiment of the present invention, by implementing the CNN and the NODE models together and in a specific order as described, improves both the efficiency and the prediction accuracy of the pure CNN model and the pure NODE model.

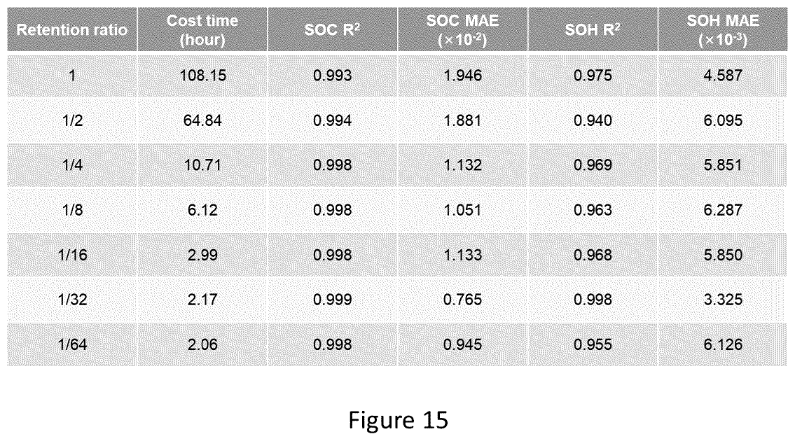

FIG. 15 is a table comparing the computational complexity with the dimensionality retention ratio of the data. When the dimensionality retention ratio is ½ of the original data, the computation time is greatly reduced. When the dimensionality retention ratio is 1/64 of the original data, the computation time decreases slightly, but the SOC & SOH prediction errors increase. Therefore, the dimension of the reduced data set is between 1/64 and ½ of the original time series data.

The invention has been given by way of example only, and various other modifications of and/or alterations to the described embodiment may be made by persons skilled in the art without departing from the scope of the invention as specified in the appended claims.

1. A method for predicting a state parameter for a battery, comprising steps of:
(i) obtaining an input dataset comprising time series voltage and current data of the battery during a portion of a charge cycle or a discharge cycle;
(ii) reducing dimensionality of the input dataset by a first neural network to form a reduced dataset with a predetermined dimension;
(iii) extracting temporal dynamic features from the reduced dataset by a second neural network, wherein the second neural network processes the reduced dataset by a neural ordinary differential equation; and
(iv) predicting the state parameter based on the extracted temporal dynamic features.

2. The method of claim 1, further comprising a step of subjecting the extracted temporal dynamic features to a pull and drop by a third neural network, prior to predicting the state parameter in step (iv).

3. The method of claim 2, further comprising a step of applying a sliding window to the input dataset, wherein the sliding window divides the input dataset into a plurality of segments over time, such that a state parameter is predicted for each of the plurality of segments.

4. The method of claim 3, wherein the sliding window has a width of an hour.

5. The method of claim 3, further comprising a step of integrating an embedding layer comprising temperature data of the battery to the extracted temporal dynamic features, prior to predicting the state parameter in step (iv).

6. The method of claim 5, wherein the temperature data of each of the plurality of segments is an averaged temperature within a respective segment.

7. The method of claim 1, wherein the state parameter is selected from any one of a state of charge, a state of health, a capacity, a state of power, a remaining useful life of the battery, or a combination thereof.

8. The method of claim 3, further comprising a step of feeding an averaged state parameter to the third neural network for training thereof, wherein the averaged state parameter is a weighted average of a plurality of state parameters predicted from the plurality of segments within the same charge cycle or the same discharge cycle.

9. The method of claim 8, wherein the state parameter comprises two or more state parameters comprising a state of charge, a state of health, a capacity, a state of power, a remaining useful life of the battery, wherein the two or more state parameters are simultaneously predicted.

10. The method of claim 1, wherein the first neural network is selected from any one of an autoencoder, a recurrent neural network, a convolutional neural network, a generative adversarial network, an attention-based network, a long short-term memory, a gated recurrent unit, or a combination thereof.

11. The method of claim 1, wherein the second neural network is an ordinary differential equation based neural network.

12. The method of claim 2, wherein the third neural network is selected from any one of an autoencoder, a recurrent neural network, a convolutional neural network, a generative adversarial network, an attention-based network, a long short-term memory, a gated recurrent unit, or a combination thereof.

13. The method of claim 1, further comprises a step of confirming whether the reduced dataset has reached the predetermined dimension, prior to extracting the temporal dynamic features in step (iii).

14. The method of claim 1, wherein the predetermined dimension of the reduced dataset is between 1/64 and ½ of a dimension of the input dataset.
